(19) United States
(12) Patent Application Publication
(10) Pub. No.: US 2026/0059742 A1
(43) Pub. Date: Feb. 26, 2026

(54) SEMICONDUCTOR MEMORY DEVICE AND METHOD OF MANUFACTURING THE SAME

(71) Applicant: Samsung Electronics Co., Ltd., Suwon-si (KR)

(72) Inventors: Seong Won Cho, Suwon-si (KR); Jung Un Kim, Suwon-si (KR); Hana Cho, Suwon-si (KR); Deokhwan Choi, Suwon-si (KR)

(21) Appl. No.: 19/194,649

(22) Filed: Apr. 30, 2025

(30) Foreign Application Priority Data
Aug. 20, 2024 (KR) 10-2024-0110941

(51) Int. Cl. H10B 12/00

(52) U.S. Cl. CPC H10B 12/482; H10B 12/033; H10B 12/315; H10B 12/488

(57) ABSTRACT

A semiconductor memory device may include a substrate; a plurality of bit lines on the substrate, spaced apart from each other in a first direction, and extending in a second direction that intersects the first direction; a plurality of channel patterns on the bit lines and extending in a third direction that is perpendicular to the first direction and the second direction; word lines on side surfaces of the channel patterns and extending in the first direction; and a gate insulating film between the channel patterns and each of the word lines, where the channel patterns have respective oval shapes in a horizontal cross-section.

### CROSS-REFERENCE TO RELATED APPLICATION

This application claims priority to Korean Patent Application No. 10-2024-0110941, filed in the Korean Intellectual Property Office on Aug. 20, 2024, the entire contents of which are hereby incorporated by reference.

### FIELD

The present disclosure relates to a semiconductor memory device and a method of manufacturing the same.

### BACKGROUND

Semiconductor devices may be main components used to control or amplify electrical signals in electronic devices, and various types of semiconductor devices can be manufactured. For example, memory devices may be mainly used to store and retrieve data, while non-memory devices may be used to control or amplify electrical signals. Semiconductor devices may be main components in electronic devices, and may play an important role in a variety of fields including computers, communications equipment, and consumer electronics.

With development of industries, requirements on performance and functionality of electronic devices have been increasing. High performance characteristics of semiconductor devices may thus be important, and the integration of semiconductor devices has been increasing to meet these requirements. Accordingly, a transistor with a vertical channel has been proposed to improve the integration of semiconductor devices.

### SUMMARY

The present disclosure provides semiconductor memory devices with improved electrical characteristics and reliability.

The present disclosure provides methods of manufacturing a semiconductor memory device with improved electrical characteristics and reliability.

According to some embodiments of the present disclosure, a semiconductor memory device includes: a substrate; a plurality of bit lines on the substrate, spaced apart from each other in a first direction, and extending in a second direction that intersects the first direction; a plurality of channel patterns on the bit lines and extending in a third direction perpendicular to the first direction and the second direction; a plurality of word lines on side surfaces of the channel patterns and extending in the first direction; and a gate insulating film between the channel patterns and the word lines, where the channel patterns have respective oval shapes in a horizontal cross-section.

According to some embodiments of the present disclosure, a semiconductor memory device includes: a substrate; a plurality of bit lines on the substrate, spaced apart from each other in a first direction, and extending in a second direction that intersects the first direction; a plurality of channel patterns on the bit lines and extending in a third direction perpendicular to the first direction and the second direction; a plurality of word lines on side surfaces of the channel patterns and extending in the first direction; a gate insulating film between the channel patterns and one of the word lines, and extending in the third direction; a plurality of pad contacts on the channel patterns; a plurality of landing pads on the pad contacts; and a capacitor structure that is electrically connected to the landing pads, where the channel patterns have respective oval shapes in a horizontal cross-section, and the landing pads are arranged in a honeycomb or hexagonal structure in a plan view.

According to some embodiments of the present disclosure, a method of manufacturing a semiconductor memory device includes: forming a laminated structure by sequentially laminating a first sacrificial layer, a semiconductor layer, and a second sacrificial layer on a preliminary substrate; patterning the laminated structure; forming a gate insulating film extending around a side surface of a channel pattern formed by patterning the semiconductor layer; forming a word line extending around a side surface of the gate insulating film; forming a pad contact by removing the second sacrificial layer of the laminated structure that was patterned; forming a landing pad on the pad contact; and forming a bit line by removing the first sacrificial layer of the laminated structure that was patterned, where the channel pattern has an oval shape a horizontal cross-section.

According to some embodiments of the present disclosure, a cross-section of the channel pattern has an oval shape, and thus, a vulnerability in high electric fields, such as a deterioration of a semiconductor memory device, can be improved. Therefore, reliability of the semiconductor memory device can be improved.

According to some embodiments of the present disclosure, the pad contact and the bit line that are connected to the channel pattern can be formed by selectively removing the sacrificial layer that is formed in advance at a location where the pad contact and the bit line are to be formed, and replacing the removed portion with a conductive material. Thereby, complexity of the manufacturing process may be reduced and reliability and electrical characteristics of the semiconductor memory device may be improved.

### BRIEF DESCRIPTION OF THE DRAWINGS

FIG. 1 is a plan view illustrating a semiconductor memory device according to some embodiments of the present disclosure.

FIG. 2 is a cross-sectional view taken along a line A-A of FIG. 1.

FIG. 3 is a cross-sectional view taken along a line B-B of FIG. 1.

FIG. 4 is an enlarged view illustrating a R1 region of FIG. 1.

FIG. 5 is an enlarged view illustrating a R1 region of FIG. 1.

FIG. 6 is a diagram illustrating a semiconductor memory device according to some embodiments of the present disclosure.

FIG. 7 is a diagram illustrating a semiconductor memory device according to some embodiments of the present disclosure.

FIG. 8 is a plan view illustrating a semiconductor memory device according to some embodiments of the present disclosure.

FIG. 9 is a cross-sectional view taken along a line B-B of FIG. 8.

FIG. 10 is an enlarged view illustrating a R2 region of FIG. 8.

FIG. 11 is an enlarged view illustrating a R2 region of FIG. 8.

FIG. 12, 13, 14, 15, 16, 17, 18, 19, 20, 21, 22, 23, 24, 25, 26, 27, 28, and FIG. 29 are diagrams illustrating a method of manufacturing a semiconductor memory device according to some embodiments of the present disclosure.

FIG. 30 is a flowchart of a method for manufacturing a semiconductor memory device according to some embodiments of the present disclosure.

### DETAILED DESCRIPTION OF EMBODIMENTS

Hereinafter, a semiconductor memory device and a method of manufacturing the same according to some embodiments of the present disclosure will be described in detail with reference to the drawings. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present.

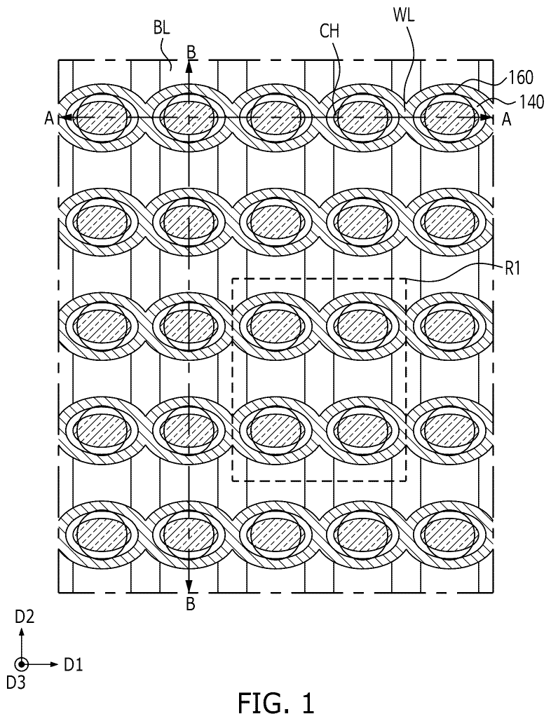

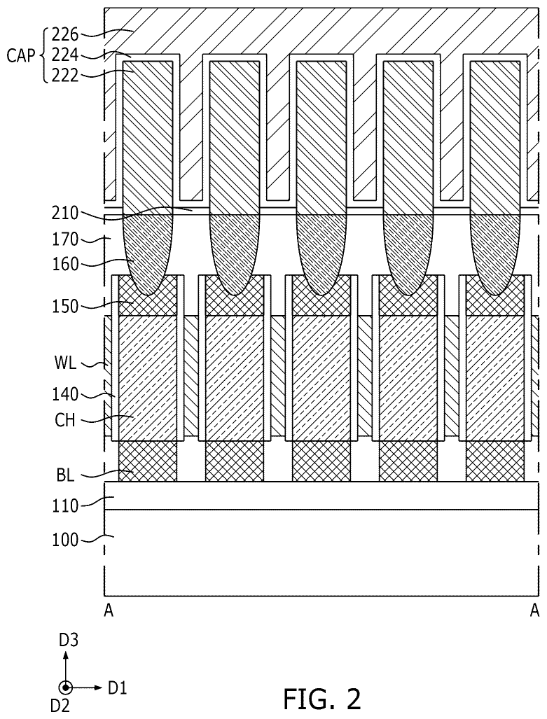

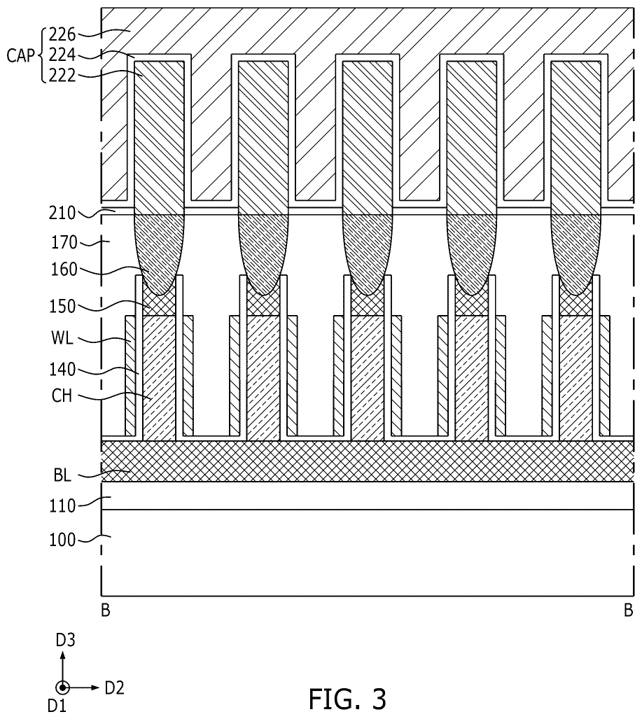

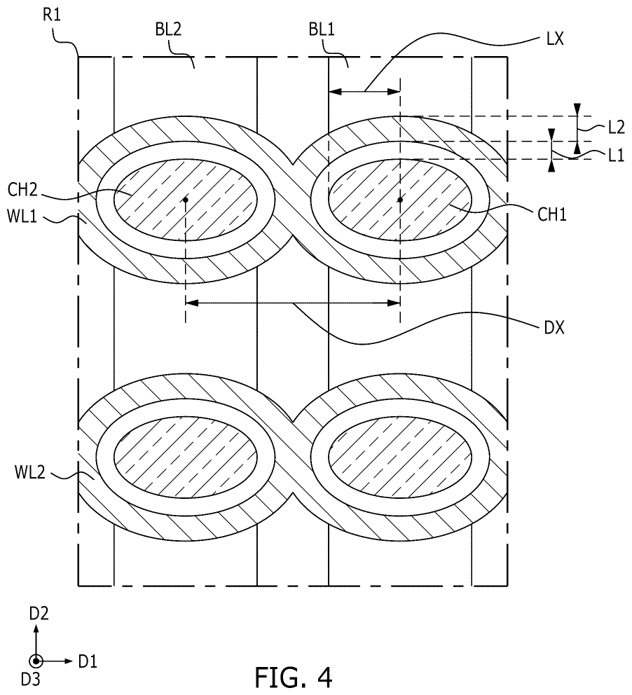

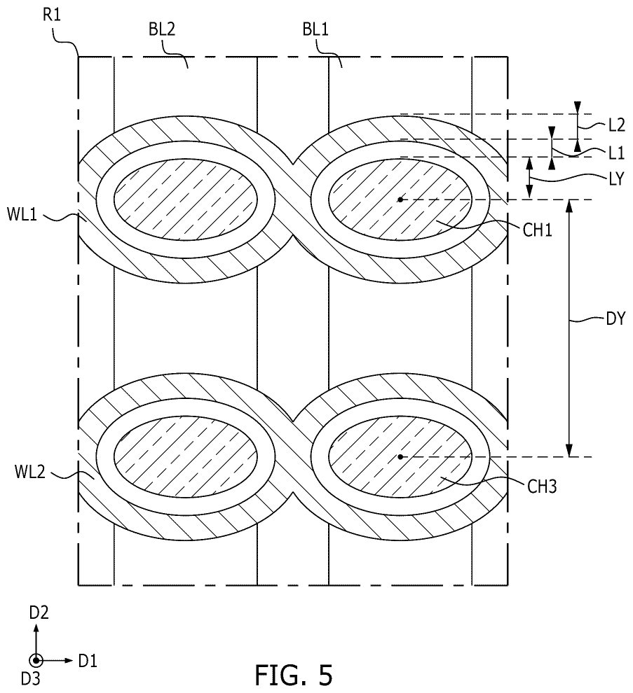

FIG. 1 is a plan view illustrating a semiconductor memory device according to some embodiments of the present disclosure. FIG. 2 is a cross-sectional view taken along a line A-A of FIG. 1. FIG. 3 is a cross-sectional view taken along a line B-B of FIG. 1. FIG. 4 and FIG. 5 are enlarged views illustrating a R1 region of FIG. 1. For reference, in FIG. 1, a dielectric film 224 and an upper electrode 226 of a capacitor structure CAP are not illustrated. It will be understood that spatially relative terms such as “above,” “upper,” “upper surface,” “below,” “lower,” “lower surface,” “side surface,” and the like may be denoted by reference numerals and refer to the drawings, except where otherwise indicated. It will be understood that such spatially relative terms are intended to encompass different orientations of the device in use or operation in addition to the orientation depicted in the figures.

A semiconductor memory device according to some embodiments of the present disclosure may include memory cells including vertical channel transistors (VCTs). The vertical channel transistor may refer to a transistor in which a channel length extends in a direction perpendicular to an upper surface of a semiconductor substrate.

Referring to FIG. 1 to FIG. 5, the semiconductor memory device according to some embodiments may include a substrate 100, a wiring insulating film 110, a bit line BL, a channel pattern CH, a word line WL, a gate insulating film 140, a pad contact 150, a landing pad 160, an interlayer insulating layer 170, and a capacitor structure CAP.

The substrate 100 may be a semiconductor substrate. The substrate 100 may include, for example, at least one of a material having semiconductor properties (for example, silicon (Si)), an insulating material (for example, silicon oxide), or a semiconductor or a conductor covered by an insulating material. In other embodiments, the present disclosure may not be limited thereto.

In some embodiments, a plurality of transistors that are connected to the bit lines BL may be disposed on the substrate 100. For example, a sensing transistor, a transmission transistor, a driving transistor, and the like may be disposed on the substrate 100. A type of the transistor may differ depending on a design layout of the semiconductor memory device. A region where a plurality of transistors are disposed on the substrate 100 may be referred to as a peripheral circuit region.

The wiring insulating film 110 may be disposed on the substrate 100. In some embodiments, a wiring structure may be disposed in the wiring insulating film 110. The wiring structure may electrically connect the substrate 100 and the bit line BL. For example, the plurality of transistors disposed on the substrate 100 may be electrically connected to the bit line BL via the wiring structure.

The bit line BL may be disposed on the wiring insulating film 110. Among a plurality of bit lines BL, adjacent bit lines BL may be disposed spaced apart from each other in a first direction D1. The bit line BL may extend in a second direction D2 on the wiring insulating film 110. Here, the second direction D2 may be a direction perpendicular to the first direction D1. The first and second directions D1 and D2 may also be referred to herein as first and second horizontal directions.

The bit line BL may include at least one of doped polysilicon, a metal (for example, Al, Cu, Ti, Ta, Ru, W, Mo, Pt, Ni, Co), a conductive metal nitride (for example, TiN, TaN, WN, NbN, TiAlN, TiSiN, TaSiN, RuTiN), or a conductive metal silicide or a conductive metal oxide (for example, PtO, RuO2, IrO2, SRO (SrRuO3), BSRO ((Ba,Sr)RuO3), CRO (CaRuO3), LSCo). In other embodiments, the present disclosure is not limited thereto.

The channel pattern CH may be disposed on an upper surface of the bit line BL. The channel pattern CH may be connected to the bit line BL. Each of a plurality of channel patterns CH may be disposed spaced apart from each other in the first direction D1 and the second direction D2. For example, the channel patterns CH may be disposed on each of the bit lines BL spaced apart from each other in the first direction D1. Further, the channel patterns CH may be disposed to be spaced apart from each other on each of the bit lines BL extending in the second direction D2.

In some embodiments, the channel pattern CH may be an oval pillar. The channel pattern CH may have an oval shape that is elongated in a direction in a plan view. For example, a horizontal cross-section of the channel pattern CH may have an oval shape, that is, an elliptical shape having a major axis in the first direction D1 and a minor axis in the second direction D2. As used herein, a horizontal cross-section may refer to a cross-section along a horizontal plane (e.g., a plane including the first and second directions D1 and D2), where the horizontal plane is perpendicular to a vertical direction (e.g., the third direction D3). In other embodiments, the present disclosure may not be limited thereto. For example, the channel pattern CH may have an oval shape having a major axis in any direction, e.g., any horizontal direction. Further, in some embodiments, respective ones of the plurality of channel patterns CH may include channel patterns having a major axis in directions different each other.

In some embodiments, the major axis of the horizontal cross-section of the channel pattern CH may be parallel to the first direction D1 relative to the second direction D2. That is, an angle formed by the major axis of the horizontal cross-section of the channel pattern CH and the first direction D1 may be smaller than an angle formed by the major axis of the horizontal cross-section of the channel pattern CH and the second direction D2. Further, in some embodiments, some or all of the horizontal cross-sections of the channel patterns CH may have respective major axes in substantially the same direction. In other embodiments, the present disclosure is not limited thereto, and the respective major axes of some or all of the horizontal cross-sections of the channel patterns CH may differ in direction.

In some embodiments, a width of the bit line BL may be substantially equal to a major-axis length of the channel pattern CH. For example, referring to FIG. 2, the width of the bit line BL in the first direction D1 may be substantially equal to the width of the channel pattern CH in the first direction D1, that is, the major-axis length of the channel pattern CH. In other embodiments, the present disclosure may not be limited thereto. The width of the bit line BL may be narrower or wider than the width of the channel pattern CH.

The channel pattern CH may include an oxide semiconductor. The oxide semiconductor may include, for example, at least one of InxGayZnzO, InxGaySizO, InxSnyZnzO, InxZnyO, ZnxO, ZnxSnyO, ZnxOyN, ZrxZnySnzO, SnxO, HfxInyZnzO, GaxZnySnzO, AlxZnySnzO, YbxGayZnzO, or InxGayO. In other embodiments, the present disclosure is not limited thereto. As an example, the channel pattern CH may include indium gallium zinc oxide (IGZO). The channel pattern CH may include a single layer or multiple layers of an oxide semiconductor. The channel pattern CH may include an amorphous oxide semiconductor, a crystalline oxide semiconductor, or a polycrystalline oxide semiconductor.

In some embodiments, the channel pattern CH may have bandgap energy which is higher than bandgap energy of silicon. For example, the channel pattern CH may have bandgap energy of approximately 1.5 eV to 5.6 eV. For example, the channel pattern CH may have optimal channel performance when the channel pattern CH has bandgap energy of approximately 2.0 eV to 4.0 eV. For example, the channel pattern CH may be polycrystalline or amorphous. In other embodiments, the present disclosure is not limited thereto.

In some embodiments, the channel pattern CH may include a two-dimensional semiconductor material. The two-dimensional semiconductor material may include, for example, graphene, carbon nanotubes, or a combination thereof.

The word line WL may be disposed on the channel pattern CH. The word line WL may intersect the bit line BL. The word line WL may extend in the first direction D1. Among a plurality of word lines WL, adjacent word lines WL may be disposed to be spaced apart from each other in the second direction D2.

In some embodiments, the semiconductor memory device may have a gate all around (GAA) structure. For example, each of the plurality of word lines WL may be disposed to surround a side surface of each of the plurality of channel patterns CH having an oval pillar shape. For example, referring to FIG. 4, the word lines extending in the first direction D1 may be integrally formed to surround side surfaces of the first channel pattern CH1 and the second channel pattern CH2. It will be understood that the term “surround” (or “cover” or “fill”) as may be used herein may not require completely surrounding or covering or filling the described elements or layers, but may, for example, refer to partially surrounding or covering or filling the described elements or layers, for example, with voids or other discontinuities throughout.

The word line WL may include, for example, at least one of doped polysilicon, a metal (for example, Al, Cu, Ti, Ta, Ru, W, Mo, Pt, Ni, Co), a conductive metal nitride (for example, TiN, TaN, WN, NbN, TiAlN, TiSiN, TaSiN, RuTiN), or a conductive metal silicide or a conductive metal oxide (for example, PtO, RuO2, IrO2, SRO (SrRuO3), BSRO ((Ba,Sr)RuO3), CRO (CaRuO3), LSCo). In other embodiments, the present disclosure is not limited thereto. The word line WL may include a single layer of each of the above-described materials or multiple layers of the above-described materials.

In some embodiments, the word line WL may include a two-dimensional semiconductor material. The two-dimensional semiconductor material may include, for example, graphene, carbon nanotubes, or a combination thereof.

The gate insulating film 140 may be disposed on a side surface of each of the channel pattern CH and the pad contact 150. The gate insulating film 140 may extend along a profile of each of the channel pattern CH and the pad contact 150. For example, the gate insulating film 140 may be disposed to directly surround a side surface of the channel pattern CH having an oval pillar shape. Further, the gate insulating film 140 may be disposed to directly surround a side surface of the pad contact 150 having an oval pillar shape. Further, the gate insulating film 140 may extend in a third direction D3 along the side surface of each of the channel pattern CH and the pad contact 150 from a vertical level corresponding to an upper surface of the pad contact 150 to a vertical level corresponding to a lower surface of the channel pattern CH.

The gate insulating film 140 may be disposed between the channel pattern CH and the word line WL. The word line WL may not be in contact with the channel pattern CH by the gate insulating film 140.

In some embodiments, the gate insulating film 140 may be disposed on the bit line BL. For example, the gate insulating film 140 may be disposed along the upper surface of the bit line BL at a point or between areas where the channel patterns CH and the bit line BL are in contact with each other. At least a portion of the gate insulating film 140 may be disposed between the word line WL and the bit line BL. The word line WL and the bit line BL may not be in contact with each other and may be separated from each other by the gate insulating film 140.

In some embodiments, the gate insulating film 140 may be further disposed on a side surface of the bit line BL. For example, although not illustrated, the gate insulating film 140 disposed on the upper surface of the bit line BL or on the side surface of the channel pattern CH may further extend in the third direction D3 to cover at least a portion of the side surface of the bit line BL.

The gate insulating film 140 may include at least one of silicon oxide, silicon oxynitride, or a high-dielectric-constant material having a dielectric constant higher than a dielectric constant of silicon oxide. The high-dielectric-constant material may include a metal oxide or a metal oxynitride. For example, the high-dielectric-constant material that can be used as the gate insulating film 140 may include at least one of HfO2, HfSiO, HfSiON, HfTaO, HfTiO, HfZrO, ZrO2, or Al2O3. In other embodiments, the present disclosure is not limited thereto.

In some embodiments, the channel patterns CH that are adjacent to each other in the first direction D1 among the plurality of channel patterns CH may be disposed such that a distance between the channel patterns CH is equal to or shorter than a predetermined distance. For example, referring to FIG. 4, a distance DX between a center point of the first channel pattern CH1 and a center point of the second channel pattern CH2 may be shorter than twice the sum of a major-axis radius LX of the channel pattern CH, a thickness L1 of the gate insulating film, and a thickness L2 of the word line, as measured in a horizontal direction (e.g., the first direction D1). In some embodiments, a length (for example, a length in the first direction D1) of the word line disposed between the gate insulating film surrounding the first channel pattern CH1 and the gate insulating film surrounding the second channel pattern CH2 may be shorter than twice the thickness L2 of the word line. Here, the first channel pattern CH1 and the second channel pattern CH2 may be spaced apart from each other in the first direction D1. The first channel pattern CH1 and the second channel pattern CH2 may be respectively disposed on the first bit line BL1 and the second bit line BL2.

In some embodiments, the channel patterns CH that are adjacent to each other in the second direction D2 among the plurality of channel patterns CH may be disposed such that a distance between the channel patterns CH is equal to or longer than a predetermined distance. For example, referring to FIG. 5, a distance DY between a center point of the first channel pattern CH1 and a center point of the third channel pattern CH3 may be longer than twice the sum of a minor-axis radius LY of the channel pattern CH, a thickness L1 of the gate insulating film, and a thickness L2 of the word line, as measured in a horizontal direction (e.g., the second direction D2). Here, the first channel pattern CH1 and the third channel pattern CH3 may be spaced apart from each other in the second direction D2. The first channel pattern CH1 and the third channel pattern CH3 may be disposed on the first bit line BL1. The first channel pattern CH1 and the third channel pattern CH3 may be respectively disposed on the first word line WL1 and the second word line WL2.

In the above-described embodiments, the first channel pattern CH1 and the second channel pattern CH2 may have substantially the same major-axis radius (for example, LX). Further, the first channel pattern CH1 and the third channel pattern CH3 may have substantially the same minor-axis radius (for example, LY). Further, the first to third channel patterns (CH1, CH2, CH3) may have substantially the same radius in both the major axis and the minor axis.

In the above-described embodiments, the thickness L1 of the gate insulating film and the thickness L2 of the word line may represent a thickness in the second direction D2. In other embodiments, the present disclosure may not be limited thereto. For example, the thickness L1 of the gate insulating film may represent a thickness of the gate insulating film 140 in any direction, or an average thickness of the gate insulating film surrounding the channel pattern CH. Further, the thickness L2 of the word line may represent a thickness of the word line WL in any direction, or an average thickness of the word line WL surrounding the gate insulating film 140.

The pad contact 150 may be disposed on the channel pattern CH. In some embodiments, a shape of a horizontal cross-section of the pad contact 150 may correspond to the shape of the horizontal cross-section of the channel pattern CH. For example, the pad contact 150 may have an oval shape that is elongated in a direction in a plan view. For example, a horizontal cross-section of the pad contact 150 may have an oval shape having a major axis in the first direction D1 and a minor axis in the second direction D2. In other embodiments, the present disclosure may not be limited thereto. For example, the pad contact 150 may have an oval shape that has a major axis in any direction, which may (in some embodiments) correspond to the horizontal cross-section of the channel pattern CH. The cross-section of the channel pattern has an oval shape, and thus, a vulnerability in high electric fields, such as a deterioration of a semiconductor memory device, can be improved. That is, channel patterns having elliptical shapes in cross-section (i.e. with reduced curvature in comparison to circular cross-sections) may be less vulnerable to high electric fields. Therefore, reliability of the semiconductor memory device can be improved.

The pad contact 150 may include at least one of doped polysilicon, a metal (for example, Al, Cu, Ti, Ta, Ru, W, Mo, Pt, Ni, Co), a conductive metal nitride (for example, TiN, TaN, WN, NbN, TiAlN, TiSiN, TaSiN, RuTiN), or a conductive metal silicide or a conductive metal oxide (for example, PtO, RuO2, IrO2, SRO (SrRuO3), BSRO ((Ba,Sr)RuO3), CRO (CaRuO3), LSCo). In other embodiments, the present disclosure is not limited thereto.

The landing pad 160 may be disposed on the pad contact 150. The landing pad 160 may be in contact with the pad contact 150. For example, the landing pad 160 may be in contact with the pad contact 150 by penetrating at least a portion of an upper surface of the pad contact 150. The landing pad 160 may be electrically connected to the channel pattern CH via the pad contact 150.

The landing pad 160 may have various shapes in a plan view, such as a circular shape, an oval shape, a rectangular shape, a square shape, a diamond shape, or a hexagonal shape, which may or may not correspond to the shapes of the pad contact 150. In a plan view, the landing pads 160 may be arranged in various shapes or patterns, such as a matrix pattern, a zigzag pattern, a honeycomb pattern, or the like, along the first direction D1 and the second direction D2. An upper surface of the landing pad 160 may be disposed on the same plane as a plane on which an upper surface of the interlayer insulating layer 170 is disposed. In other embodiments, the present disclosure may not be limited thereto.

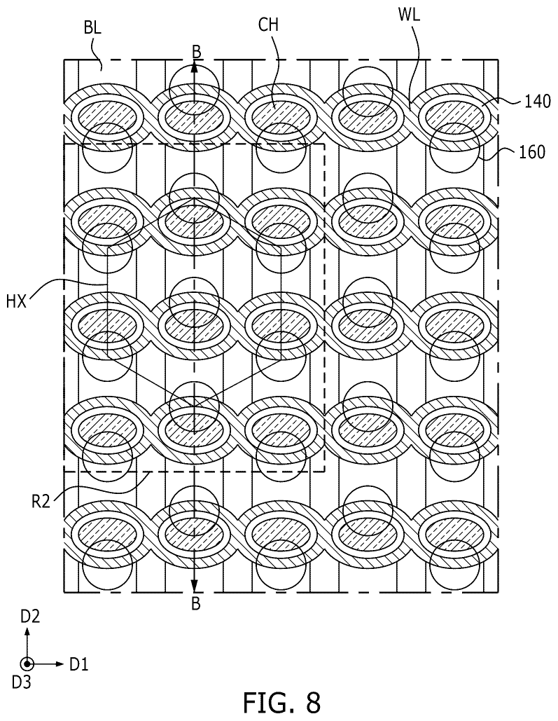

The landing pad 160 may overlap the pad contact 150 in the third direction D3. Components or layers described with reference to “overlap” in a particular direction may be at least partially obstructed by one another when viewed along a line extending in the particular direction or in a plane perpendicular to the particular direction. For example, a center point of the landing pad 160 and a center point of the pad contact 150 may be aligned in the third direction D3. In other embodiments, the present disclosure may not be limited thereto. The center point of the landing pad 160 may be formed to be spaced apart from the center point of the pad contact 150, e.g., in a horizontal direction when viewed in plan view. A detailed explanation thereof will be described with reference to FIG. 8 to FIG. 11.

The landing pad 160 may be made of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof. In other embodiments, the present disclosure is not limited thereto.

The interlayer insulating layer 170 may be disposed on the bit line BL, the word line WL, the gate insulating film 140, the pad contact 150, and the landing pad 160. The interlayer insulating layer 170 may fill an empty space between structures, such as the bit line BL, the word line WL, the gate insulating film 140, the pad contact 150, the landing pad 160, and the like, from the lower surface (or the upper surface) of the bit line BL to the upper surface of the landing pad 160. The interlayer insulating layer 170 may include an insulating material. The interlayer insulating layer 170 may include, for example, at least one of silicon oxide, silicon nitride, silicon oxynitride, or a low-dielectric-constant insulating material.

An etching stop film 210 may be disposed on the landing pad 160 and the interlayer insulating layer 170. The etching stop film 210 may expose the landing pad 160. The term “expose” may be used to describe relationships between elements and/or certain intermediate processes in fabricating a completed semiconductor device, but may not necessarily require exposure of the particular region, layer, structure or other element in the context of the completed device.

The capacitor structure CAP may be disposed on the landing pad 160 and the interlayer insulating layer 170. The capacitor structure CAP may store signals received from transistors in peripheral circuit structures (for example, a row/column decoder, a sense amplifier, and the like) of the semiconductor memory device. The capacitor structure CAP may be used as an information storage element that is electrically connected to the transistor. For example, the capacitor structure CAP may store charges under a control of the transistor.

The capacitor structure CAP may include a lower electrode 222, a dielectric film 224, and an upper electrode 226.

The lower electrode 222 may be disposed on the landing pad 160. The lower electrode 222 may be electrically connected to the landing pad 160. A portion of the lower electrode 222 may be disposed in the etching stop film 210. For example, the lower electrode 222 may penetrate the etching stop film 210 to be connected to the landing pad 160.

The lower electrode 222 may include at least one of, for example, a conductive metal material (cobalt (Co), titanium (Ti), nickel (Ni), tungsten (W), molybdenum (Mo), or the like), a metal nitride (titanium nitride (TiN), titanium silicon nitride (TiSiN), titanium aluminum nitride (TiAlN), tantalum aluminum nitride (TaAlN), tungsten nitride (WN), or the like), a precious metal material (platinum (Pt), ruthenium (Ru), iridium (Ir), or the like), a conductive oxide film (PtO, RuO2, IrO2, SRO (SrRuO3), BSRO ((Ba,Sr)RuO3), CRO (CaRuO3), LSCo, or the like), or a metal silicide film. In other embodiments, the present disclosure may not be limited thereto.

Although not illustrated, in some embodiments, at least one supporter may be disposed between the lower electrodes 222. The supporter may support the lower electrode 222.

The dielectric film 224 may be disposed on the lower electrode 222. The dielectric film 224 may extend along a profile of the lower electrode 222. The dielectric film 224 may include, for example, a high-dielectric-constant material including silicon oxide, silicon nitride, silicon oxynitride, and a metal. The dielectric film 224 is illustrated as a single film for convenience of explanation. In other embodiments, the present disclosure is not limited thereto. Although the dielectric film 224 is illustrated as a single film, the dielectric film 224 may include a plurality of films.

The upper electrode 226 may be disposed on the dielectric film 224. The upper electrode 226 may fill an empty space between the lower electrodes 222. The upper electrode 226 may include, for example, at least one of an elemental semiconductor material film or a compound semiconductor material film. The upper electrode 226 may include a doped n-type impurity or a doped p-type impurity.

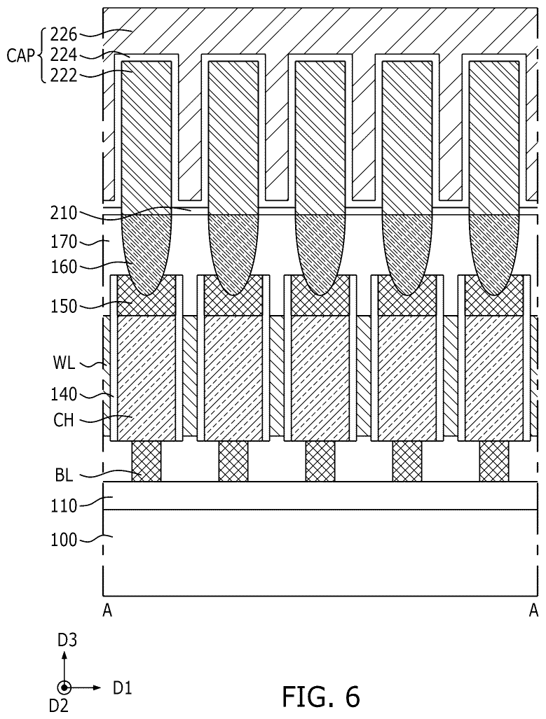

FIG. 6 is a diagram illustrating a semiconductor memory device according to some embodiments of the present disclosure. For reference, FIG. 6 may correspond to a cross-sectional view taken along a line A-A of FIG. 1. For convenience of explanation, description will be given focusing on configurations different from the configurations described in FIG. 1 to FIG. 5.

Referring to FIG. 6, in some embodiments, the width of the bit line BL may be narrower than the major-axis length of the channel pattern CH. For example, the width of the bit line BL in the first direction D1 may be narrower than the width of the channel pattern CH in the first direction D1, that is, the major-axis length of the channel pattern CH.

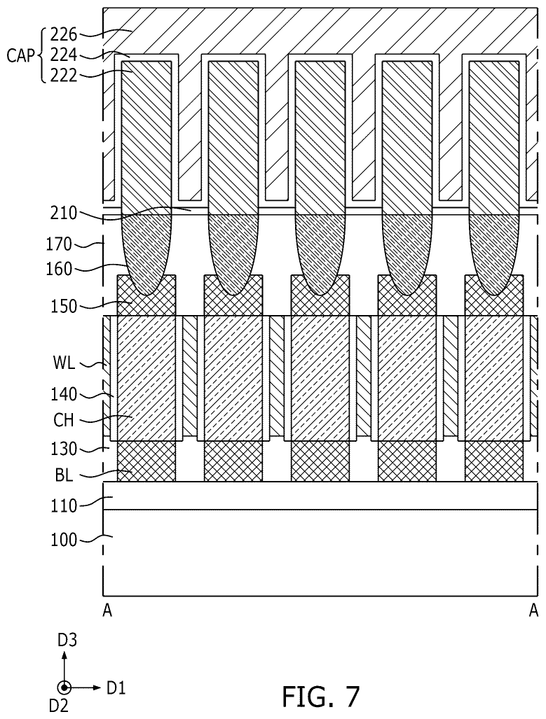

FIG. 7 is a diagram illustrating the semiconductor memory device according to some embodiments of the present disclosure. For reference, FIG. 7 may correspond to a cross-sectional view taken along a line A-A of FIG. 1. For convenience of explanation, description will be given focusing on configurations different from the configurations described in FIG. 1 to FIG. 6.

Referring to FIG. 7, in some embodiments, the gate insulating film 140 may surround the channel pattern CH. The gate insulating film 140 may extend along a profile of the channel pattern CH. For example, the gate insulating film 140 may be disposed to directly surround a side surface of the channel pattern CH having an oval pillar shape. Further, the gate insulating film 140 may extend in the third direction D3 along the side surface of the channel pattern CH from a vertical level corresponding to the upper surface of the channel pattern CH to a vertical level corresponding to the lower surface of the channel pattern CH. The term “level” or “vertical level” may be used herein to refer to a distance of an element or surface (e.g., in the third direction D3) relative to a reference element or surface, such as the substrate 100. The word line WL may not be in contact with or may be separated from the channel pattern CH by the gate insulating film 140. The pad contact 150 may be free of the gate insulating film.

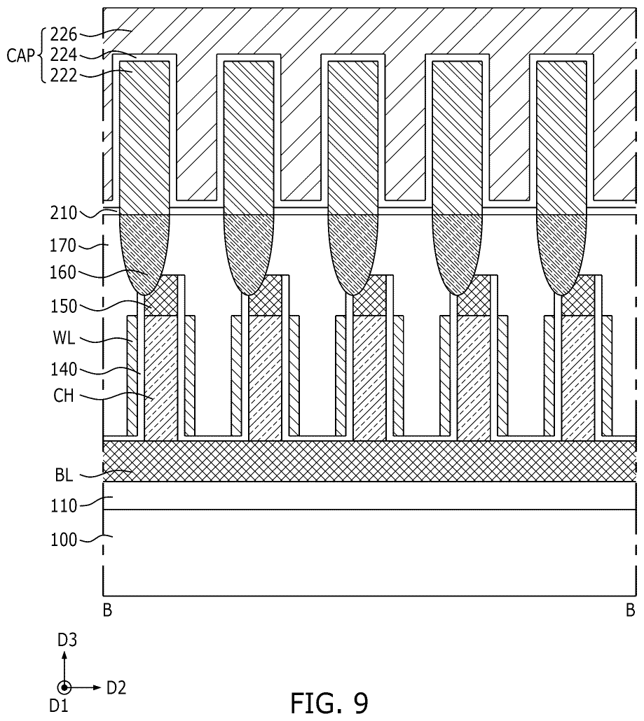

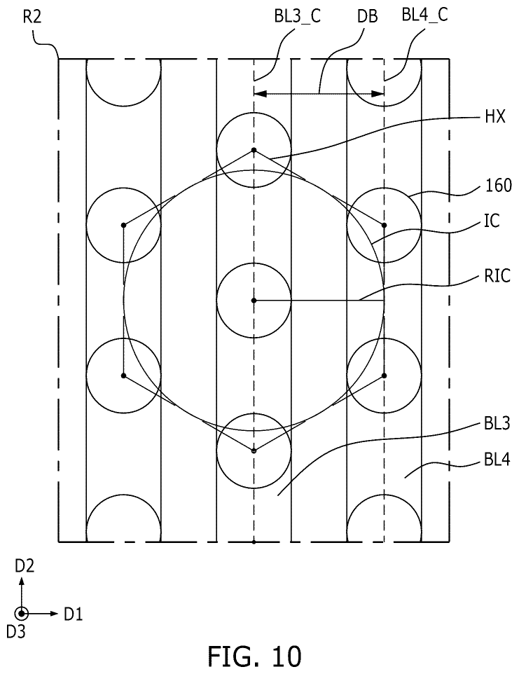

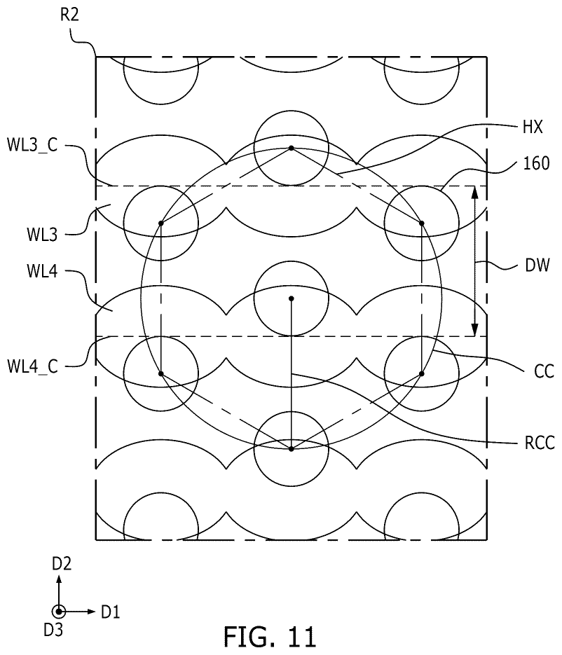

FIG. 8 is a plan view illustrating a semiconductor memory device according to some embodiments of the present disclosure. FIG. 9 is a cross-sectional view taken along a line B-B of FIG. 8. FIG. 10 and FIG. 11 are enlarged views illustrating a R2 region of FIG. 8. For reference, in FIG. 8, a dielectric film 224 and an upper electrode 226 of a capacitor structure CAP are not illustrated. Further, the semiconductor memory device of FIG. 8 to FIG. 11 may be substantially the same as the semiconductor memory device described in FIG. 1 to FIG. 7, except that the arrangement of the landing pad 160 and the lower electrode 222 has a honeycomb structure or hexagonal pattern. For convenience of explanation, description will be given focusing on configurations different from the configurations described in FIG. 1 to FIG. 7.

The landing pads 160 may be arranged in a honeycomb structure in a plan view. For example, the landing pads 160 may be disposed at each corner and a center point of a hexagonal structure HX that is repeated. A distance between the center points of adjacent landing pads 160 among a plurality of landing pads 160 may all be substantially the same.

In some embodiments, a center of the landing pad 160 may be positioned to be shifted from a center of the pad contact 150 (e.g., in a horizontal direction) by a predetermined distance, and at least a portion of the landing pad 160 may overlap the pad contact 150 in the third (or vertical) direction D3. For example, the landing pad 160 may be disposed such that the center of the landing pad 160 is shifted from the center of the pad contact 150 by a distance corresponding to 0.25 times the distance between the center points of adjacent landing pads 160. In other embodiments, the present disclosure is not limited thereto. The center of the landing pad 160 may be disposed to be shifted from the center of the pad contact 150 in the second direction D2.

In some embodiments, adjacent bit lines BL among the plurality of bit lines BL may be spaced apart from each other by a predetermined distance. For example, referring to FIG. 10, a distance DB between a center line BL3_C of the third bit line BL3 and a center line BL4_C of the fourth bit line BL4 (e.g., in the first direction D1) may be substantially equal to a radius RIC of an inscribed circle IC of the hexagonal structure HX. Here, the third bit line BL3 and the fourth bit line BL4 may be adjacent bit lines BL that are spaced apart from each other in the first direction D1.

In some embodiments, adjacent word lines WL among the plurality of word lines WL may be spaced apart from each other by a predetermined distance. For example, referring to FIG. 11, a distance DW between a center line WL3_C of the third word line WL3 and a center line WL4_C of the fourth word line WL4 (e.g., in the second direction D2) may be substantially equal to a radius RCC of a circumscribed circle CC of the hexagonal structure HX. Here, the third word line WL3 and the fourth word line WL4 may be adjacent word lines WL that are spaced apart from each other in the second direction D2.

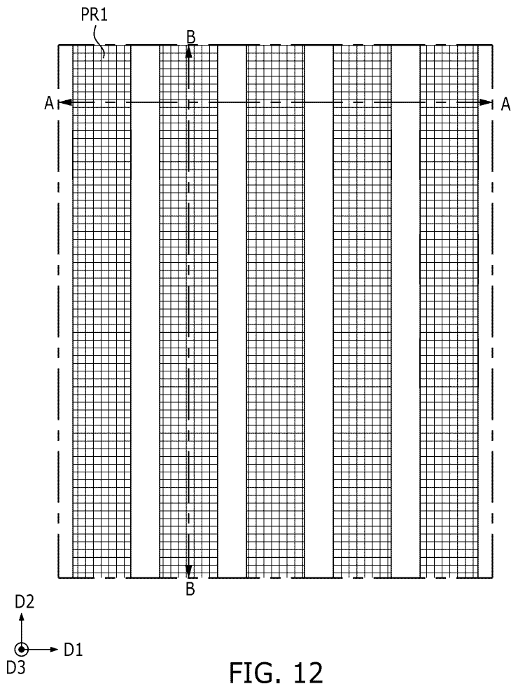

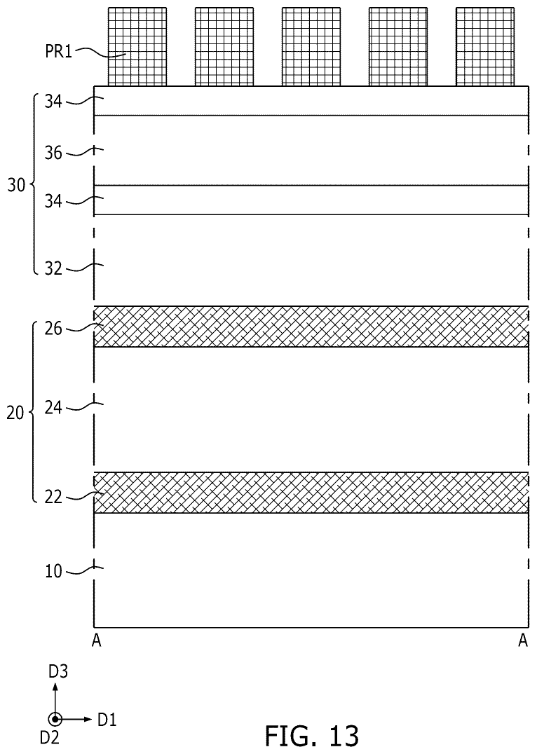

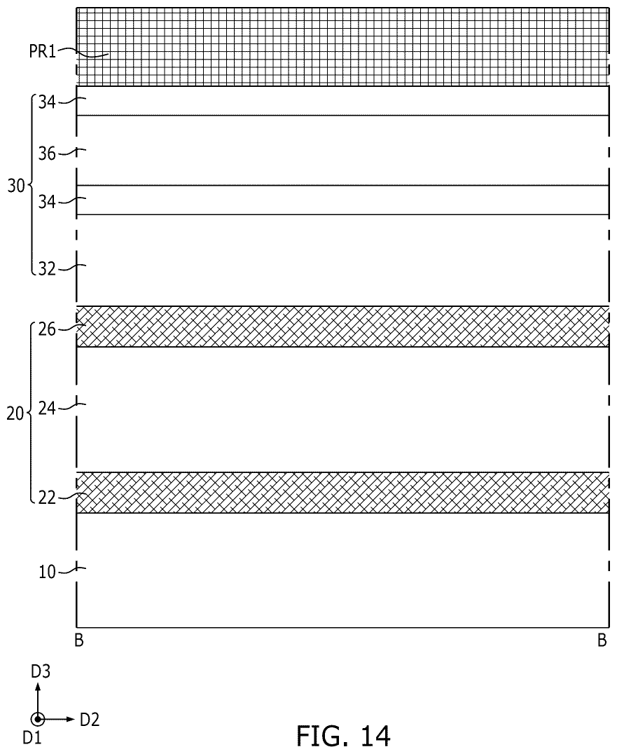

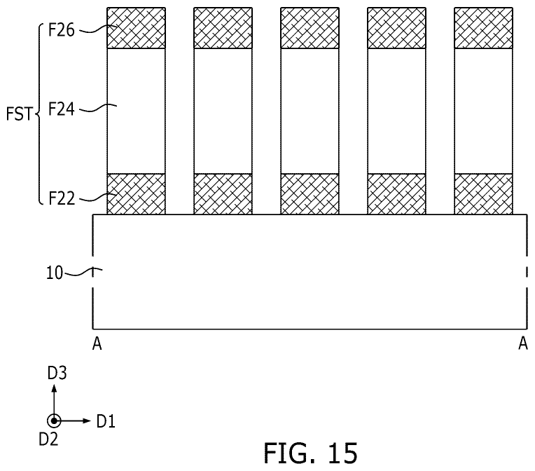

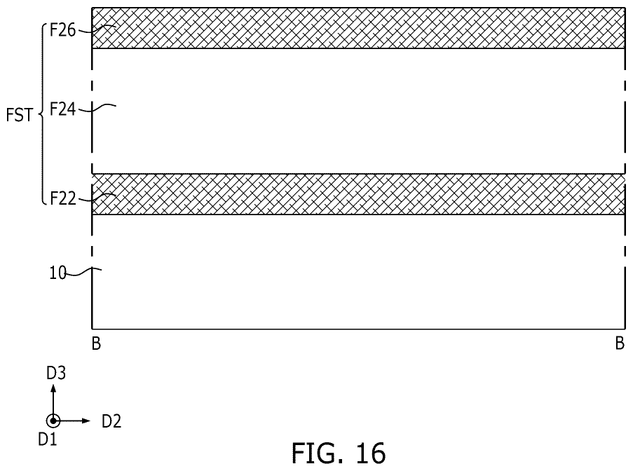

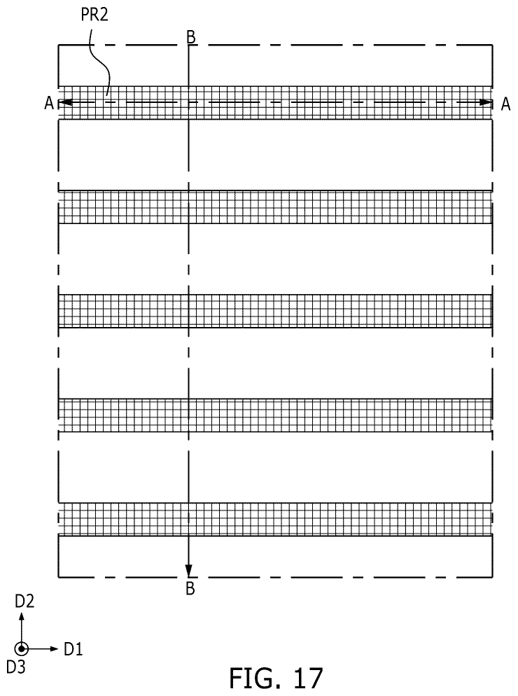

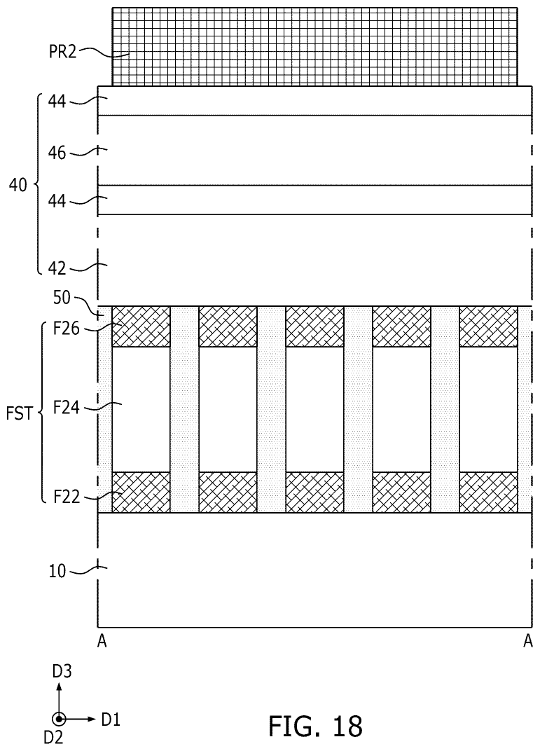

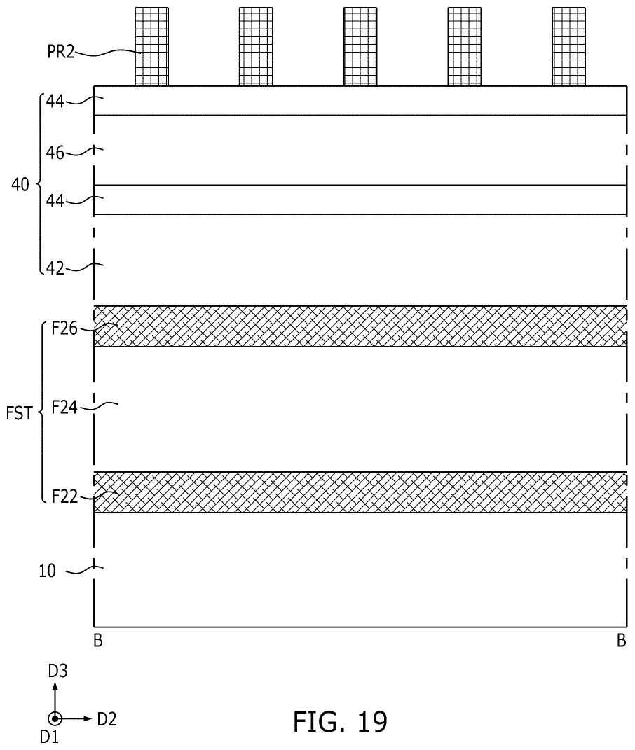

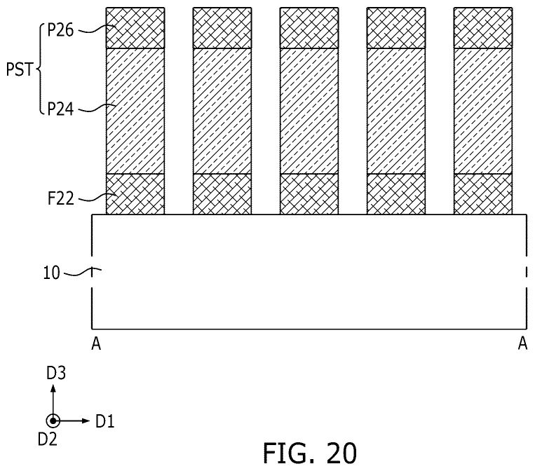

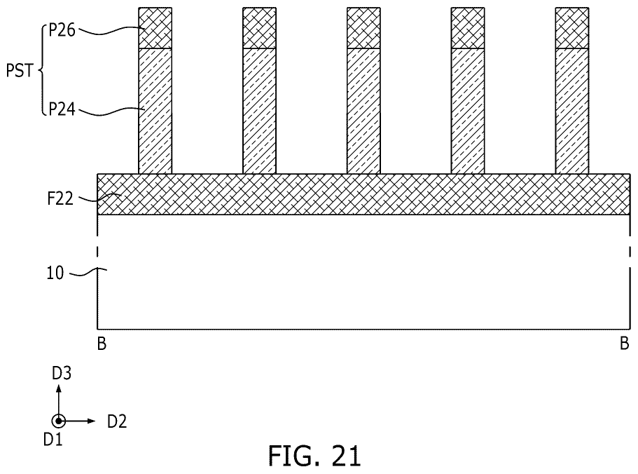

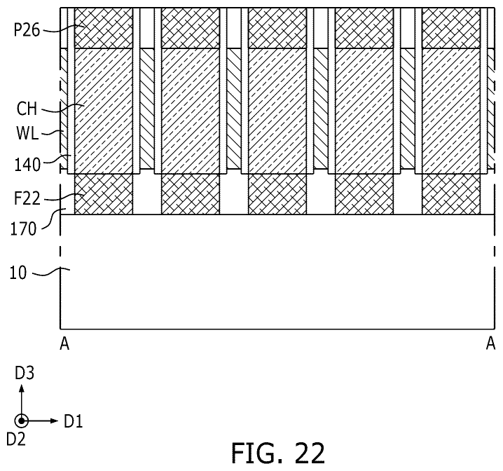

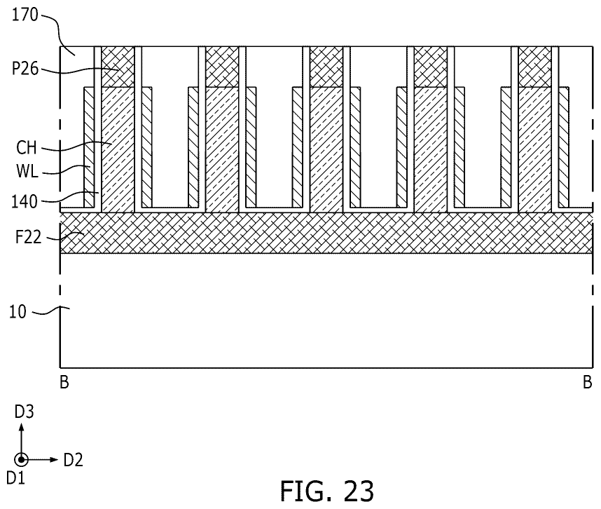

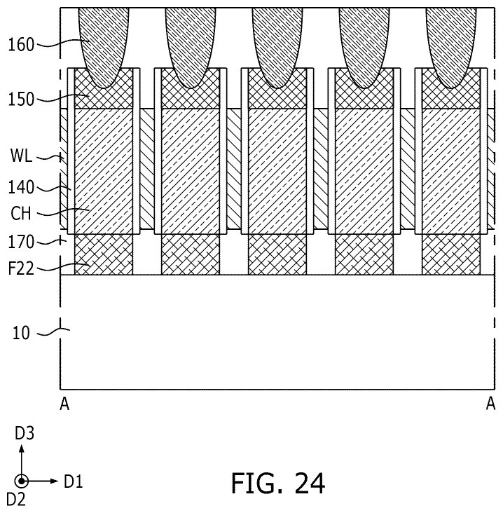

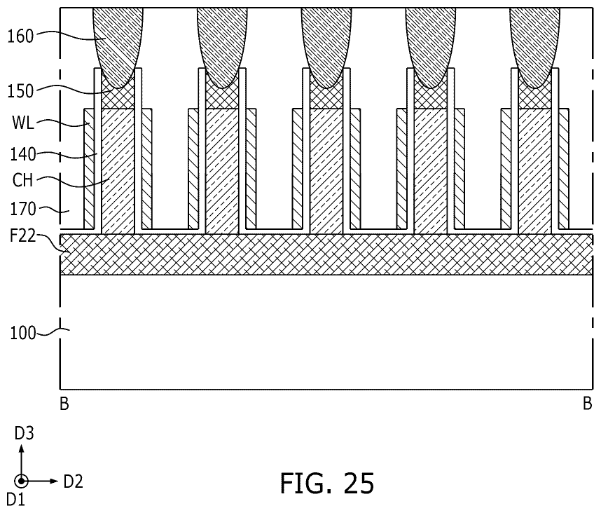

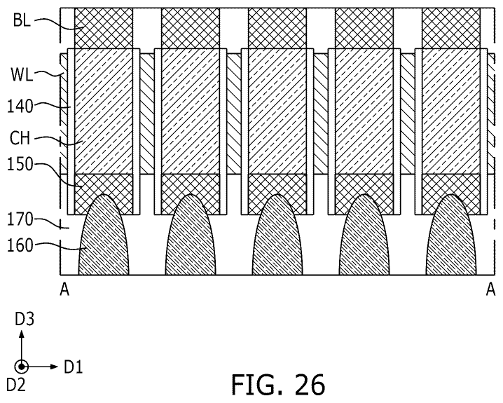

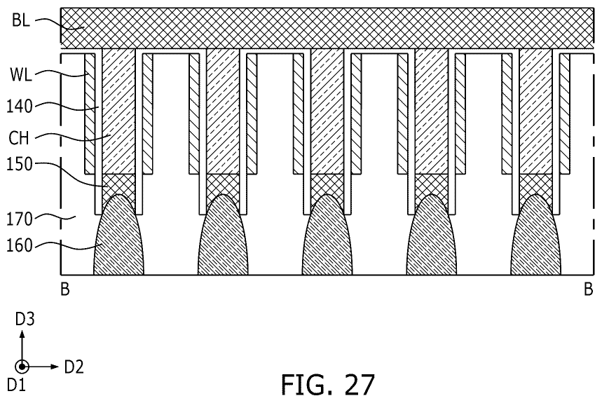

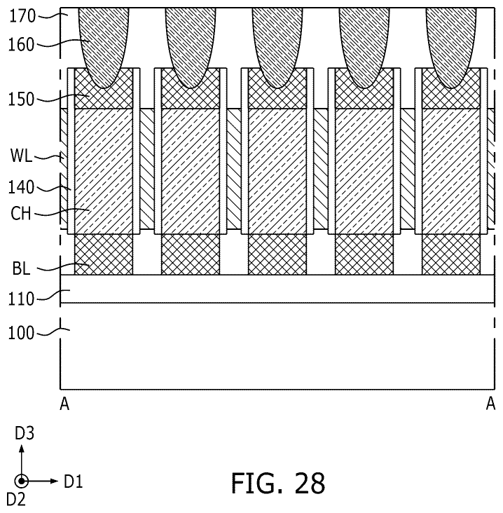

FIG. 12 to FIG. 29 are diagrams illustrating a method of manufacturing a semiconductor memory device according to some embodiments of the present disclosure. For reference, FIG. 12 and FIG. 17 are plan views at an intermediate stage of manufacturing the semiconductor memory device. FIG. 13 and FIG. 15 are diagrams corresponding to or related to a cross-sectional view taken along a line A-A of FIG. 12, and FIG. 14 and FIG. 16 are diagrams corresponding to or related to a cross-sectional view taken along a line B-B of FIG. 12. Further, FIGS. 18, 20, 22, 24, 26 and 28 are diagrams corresponding to or related to a cross-sectional view taken along a line A-A of FIG. 17, and FIGS. 19, 21, 23, 25, 27 and 29 are diagrams corresponding to or related to a cross-sectional view taken along a line B-B of FIG. 17.

Hereinafter, for convenience of explanation, the semiconductor memory device will be described with reference to FIG. 1 to FIG. 5.

Referring to FIG. 12 to FIG. 14, a laminated or laminate structure 20, a first hard mask structure 30, and first mask patterns PR1 may be formed on a preliminary substrate 10.

The preliminary substrate 10 may include, for example, at least one of a material having semiconductor properties (for example, silicon (Si)), an insulating material (for example, silicon oxide, or silicon nitride), or a semiconductor or a conductor covered by an insulating material. In other embodiments, the present disclosure may not be limited thereto.

The laminated structure 20 may include a first sacrificial layer 22, a semiconductor layer 24, and a second sacrificial layer 26 that are sequentially laminated. The first sacrificial layer 22, the semiconductor layer 24, and the second sacrificial layer 26 may be sequentially laminated on an upper surface of the preliminary substrate 10. The first sacrificial layer 22 and the second sacrificial layer 26 may include silicon nitride (SiNx). The semiconductor layer 24 may include silicon (Si). In other embodiments, the present disclosure may not be limited thereto.

In some embodiments, the laminated structure 20 may be formed by laminating the second sacrificial layer 26 on a silicon-on-insulator (SOI) substrate including the preliminary substrate 10, the first sacrificial layer 22, and the semiconductor layer 24. In other embodiments, the present disclosure may not be limited thereto.

The first hard mask structure 30 may include a carbon thin film layer 32, a hard mask insulating layer 34, and a hard mask layer 36. The carbon thin film layer 32 and the hard mask layer 36 may be disposed to be spaced apart from each other in the third direction D3 on an upper surface of the laminated structure 20, and the hard mask insulating layer 34 may be disposed between the carbon thin film layer 32 and the hard mask layer 36 and on an upper surface of the hard mask layer 36. The carbon thin film layer 32 may include an amorphous carbon layer (ACL). The hard mask insulating layer 34 may include silicon oxide nitride (SiON). The hard mask layer 36 may include an organic or inorganic hard mask material (spin-on hardmask (SOH)) formed by spin coating. In other embodiments, the present disclosure may not be limited thereto.

The first mask patterns PR1 may be formed on an upper surface of the first hard mask structure 30. The first mask patterns PR1 may be formed to be spaced apart from each other in the first direction D1 and extending in the second direction D2.

Referring to FIG. 15 and FIG. 16, the laminated structure 20 may be patterned to form fin-shaped laminated structures FST. For example, the first sacrificial layer 22, the semiconductor layer 24, and the second sacrificial layer 26 of the laminated structure 20 may be patterned in the third direction D3 by using the first mask patterns PR1 to form fin-shaped laminated structures FST. The fin-shaped laminated structures FST may be formed to be spaced apart from each other in the first direction D1 and extending in the second direction D2. The fin-shaped laminated structure FST may include the first sacrificial layer F22, the semiconductor layer F24, and the second sacrificial layer F26 each of which is patterned in a fin shape.

Referring to FIG. 17 to FIG. 19, a polysilicon layer 50 may be filled in an empty space between the fin-shaped laminated structures FST. A second hard mask structure 40 may be formed on an upper surface of the fin-shaped laminated structure FST and an upper surface of the polysilicon layer 50. The second hard mask structure 40 may include a carbon thin film layer 42, a hard mask insulating layer 44, and a hard mask layer 46. In the arrangement of the components and the material of each of the components, the second hard mask structure 40 may be identical or similar to the first hard mask structure 30.

Second mask patterns PR2 may be formed on an upper surface of the second hard mask structure 40. The second mask patterns PR2 may be formed to be spaced apart from each other in the second direction D2 and extending in the first direction D1. In some embodiments, a width of the second mask pattern PR2 in the second direction D2 may be narrower than the width of the first mask pattern PR1 in the first direction D1. A pillar structure may be patterned using the first mask pattern PR1 and the second mask pattern PR2, and a cross-sectional shape of the pillar structure may be formed in an oval shape, for example, by isotropic etching. In some embodiments, the oval shape may be an oval shape that is elongated in the first direction D1. In other embodiments, the present disclosure may not be limited thereto. For example, the second mask pattern PR2 may have an oval shape having a major axis in any direction (e.g., in any horizontal direction perpendicular to the third or vertical direction D3).

Referring to FIG. 20 and FIG. 21, a fin-shaped laminated structure FST may be patterned to form a laminated structure PST having an oval pillar or columnar shape. For example, the semiconductor layer F24 and the second sacrificial layer F26 of the fin-shaped laminated structure FST may be patterned in the third direction D3 using the second mask patterns PR2 to form a laminated structure PST having an oval pillar shape. That is, the fin-shaped laminated structure FST may be patterned from an upper surface of the second sacrificial layer F26 to a lower surface of the semiconductor layer F24, and the first sacrificial layer F22 may not be patterned. The laminated structures PST having an oval pillar shape may be arranged in a matrix form by being spaced apart from each other in the first direction D1 and the second direction D2 in a plan view. The laminated structure PST having an oval pillar shape may include the second sacrificial layer P26 that is patterned in an oval pillar shape and the channel pattern CH that is obtained by patterning the semiconductor layer P24 in an oval pillar shape.

Referring to FIG. 22 and FIG. 23, the gate insulating film 140 surrounding a side surface of the channel pattern CH may be formed. The gate insulating film 140 may be partially disposed on an upper surface of the first sacrificial layer F22 having a fin shape. In some embodiments, the gate insulating film 140 may further surround an outer surface of the second sacrificial layer P26 disposed on the channel pattern CH.

The word line WL may be formed to surround an outer surface of the gate insulating film 140. The word line WL may surround an outer surface of each of the channel patterns CH, which are arranged to be spaced apart from each other in the first direction D1, among the plurality of channel patterns CH. The word lines WL may be formed to extend in the first direction D1 and to be spaced apart from each other in the second direction D2.

The interlayer insulating layer 170 may be formed to fill an empty space between the channel patterns CH from the upper surface of the preliminary substrate 10 to the upper surface of the second sacrificial layer P26 having an oval pillar shape.

Referring to FIG. 24 and FIG. 25, the pad contact 150 may be formed by selectively removing the second sacrificial layer P26 having an oval pillar shape. The landing pad 160 may be formed to penetrate a portion of an upper surface of the pad contact 150. The landing pad 160 may be formed by patterning a portion of the interlayer insulating layer 170 formed on the pad contact 150 and filling the inside of a landing pad recess, which is formed by the patterning, with metal, metal silicide, doped polysilicon, or the like.

Referring to FIG. 26 and FIG. 27, the bit line BL may be formed by selectively removing the first sacrificial layer F22 having a fin shape. In order to form the bit line BL, a process of turning the workpiece at an intermediate stage upside down such that the upper surface of the landing pad 160 faces downward and removing the preliminary substrate 10 and the first sacrificial layer F22 may be performed.

Referring to FIG. 28 and FIG. 29, the wiring insulating film 110 and the substrate 100 may be formed on the bit line BL. A wiring structure that is electrically connected to the bit line BL may be disposed in the wiring insulating film 110. The semiconductor memory device described with reference to FIG. 1 to FIG. 11 may be manufactured by using a method that is identical or similar to the above-described method of manufacturing a semiconductor memory device.

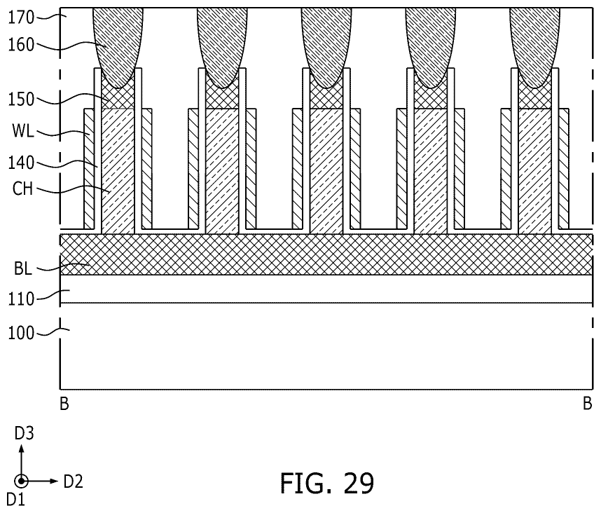

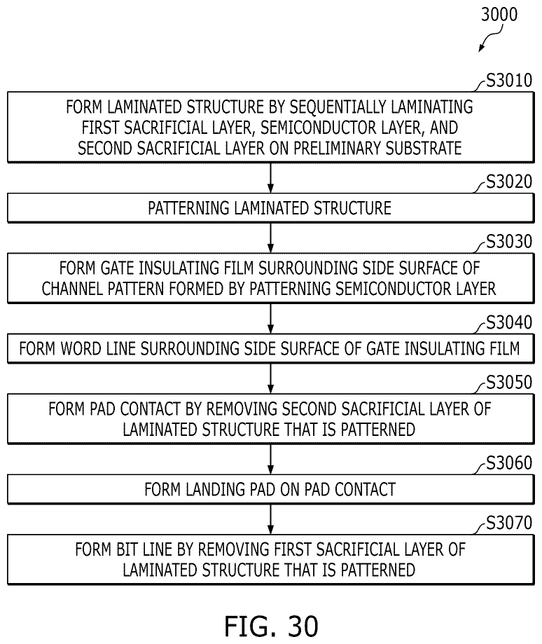

FIG. 30 is a flowchart illustrating an example of a method 3000 of manufacturing a semiconductor memory device according to some embodiments of the present disclosure.

The method 3000 may begin by sequentially laminating the first sacrificial layer, the semiconductor layer, and the second sacrificial layer on the preliminary substrate to form the laminated structure (S3010). The laminated structure may be patterned (S3020). In some embodiments, the fin-shaped laminated structure may be formed by patterning the first sacrificial layer, the semiconductor layer, and the second sacrificial layer of the laminated structure by using the first mask patterns, which are spaced apart from each other in the first direction and extend in the second direction perpendicular to the first direction. Further, the laminated structure having an oval pillar shape may be formed by patterning the semiconductor layer and the second sacrificial layer of the fin-shaped laminated structure by using the second mask patterns extending in the first direction.

The gate insulating film surrounding the side surface of the channel pattern that is formed by patterning the semiconductor layer may be formed (S3030). Here, the horizontal cross-section of the channel pattern may have an oval shape. The word line surrounding the side surface of the gate insulating film may be formed (S3040). The pad contact may be formed by removing the second sacrificial layer of the laminated structure that is patterned (S3050). The landing pad may be formed on the pad contact (S3060). The bit line may be formed by removing the first sacrificial layer of the laminated structure that is patterned (S3070). Further, a capacitor structure may be formed on the landing pad.

The pad contact and the bit line that are connected to the channel pattern may be formed by selectively removing the sacrificial layer that is formed in advance at a location where the pad contact and the bit line are to be formed, and replacing the removed portion with a conductive material. Thereby, embodiments described herein can reduce complexity of the manufacturing process and to improve reliability and electrical characteristics of the semiconductor memory device.

Although the present invention has been described above by means of some embodiments and drawings, the present invention is not limited thereto, and various modifications and variations may be made by those skilled in the art within the scope of the technical idea of the present invention and the equivalent scope of the claims to be described below.

1. A semiconductor memory device comprising:
a substrate;
a plurality of bit lines on the substrate, wherein the bit lines are spaced apart from each other in a first direction and extend in a second direction that intersects the first direction;
a plurality of channel patterns on the bit lines and extending in a third direction that is perpendicular to the first direction and the second direction;
a plurality of word lines on side surfaces of the channel patterns and extending in the first direction; and
a gate insulating film between the channel patterns and the word lines, wherein the channel patterns have respective oval shapes in a horizontal cross-section.

2. The semiconductor memory device according to claim 1, wherein, in the horizontal cross-section, the channel patterns have a major axis in the first direction and a minor axis in the second direction.

3. The semiconductor memory device according to claim 1, wherein:
the channel patterns comprise a first channel pattern and a second channel pattern, wherein the second channel pattern is spaced apart from the first channel pattern in the first direction and has a same major-axis radius as the first channel pattern, and
a distance between a center point of the first channel pattern and a center point of the second channel pattern is shorter than twice a sum of the major-axis radius, a thickness of the gate insulating film, and a thickness of the word lines.

4. The semiconductor memory device according to claim 1, wherein:
the channel patterns comprise a first channel pattern and a second channel pattern, wherein the second channel pattern is spaced apart from the first channel pattern in the second direction and has a same minor-axis radius as the first channel pattern, and
a distance between a center point of the first channel pattern and a center point of the second channel pattern is longer than twice a sum of the minor-axis radius, a thickness of the gate insulating film, and a thickness of the word lines.

5. The semiconductor memory device according to claim 1, wherein, in the first direction, a width of the bit lines is equal to or narrower than a length of a major-axis of the channel patterns.

6. The semiconductor memory device according to claim 1, wherein:
the gate insulating film extends on the bit lines, and
at least a portion of the gate insulating film is between the word lines and the bit lines.

7. The semiconductor memory device according to claim 1, further comprising:
a plurality of pad contacts on the channel patterns;
a plurality of landing pads that are on the pad contacts; and
a capacitor structure that is electrically connected to the landing pads.

8. The semiconductor memory device according to claim 7, wherein
the gate insulating film extends on side surfaces of the pad contacts.

9. The semiconductor memory device according to claim 7, wherein
at least a portion of the landing pads overlaps the pad contacts in the third direction.

10. The semiconductor memory device according to claim 1, wherein
one of the word lines extends on side surfaces of the channel patterns.

11. A semiconductor memory device comprising:
a substrate;
a plurality of bit lines on the substrate, wherein the bit lines are spaced apart from each other in a first direction and extend in a second direction that intersects the first direction;
a plurality of channel patterns on the bit lines and extending in a third direction that is perpendicular to the first direction and the second direction;
a plurality of word lines on side surfaces of the channel patterns and extending in the first direction;
a gate insulating film between the channel patterns and one of the word lines, and extending in the third direction;
a plurality of pad contacts on the channel patterns;
a plurality of landing pads on the pad contacts; and
a capacitor structure that is electrically connected to the landing pads,
wherein the channel patterns have respective oval shapes in a horizontal cross-section, and
wherein the landing pads are arranged in a hexagonal structure in a plan view.

12. The semiconductor memory device according to claim 11, wherein
the landing pads are positioned at respective vertices and at a center point of the hexagonal structure.

13. The semiconductor memory device according to claim 12, wherein:
the word lines comprise a first word line and a second word line that is spaced apart from the first word line in the second direction, and
a distance in the second direction between a center line of the first word line and a center line of the second word line is equal to a radius of a circumscribed circle of the hexagonal structure.

14. The semiconductor memory device according to claim 12, wherein:
the bit lines comprise a first bit line and a second bit line that is spaced apart from the first bit line in the first direction, and
a distance in the first direction between a center line of the first bit line and a center line of the second bit line is equal to a radius of an inscribed circle of the hexagonal structure.

15. The semiconductor memory device according to claim 11, wherein at least a portion of the landing pads overlaps the pad contacts in the third direction.

16. The semiconductor memory device according to claim 11, wherein a lower electrode of the capacitor structure is aligned with the landing pads in the third direction.

17. The semiconductor memory device according to claim 11, wherein, in the horizontal cross-section, the channel patterns have a major axis in the first direction and a minor axis in the second direction.

18. A method of manufacturing a semiconductor memory device, the method comprising:
forming a laminated structure by sequentially laminating a first sacrificial layer, a semiconductor layer, and a second sacrificial layer on a preliminary substrate;
patterning the second sacrificial layer, the semiconductor layer, and the first sacrificial layer of the laminated structure;
forming a gate insulating film extending around a side surface of a channel pattern formed by the patterning of the semiconductor layer;
forming a word line extending around a side surface of the gate insulating film;
forming a pad contact by removing the second sacrificial layer of the laminated structure that was patterned;
forming a landing pad on the pad contact; and
forming a bit line by removing the first sacrificial layer of the laminated structure that was patterned, wherein
the channel pattern has an oval shape in a horizontal cross-section.

19. The method of manufacturing a semiconductor memory device according to claim 18, wherein the patterning of the second sacrificial layer, the semiconductor layer, and the first sacrificial layer of the laminated structure comprises:
forming a fin-shaped laminated structure by patterning the second sacrificial layer, the semiconductor layer, and the first sacrificial layer of the laminated structure by using first mask patterns that are spaced apart from each other in a first direction and extend in a second direction that intersects the first direction; and
forming a laminated structure having an oval pillar shape by patterning the semiconductor layer and the second sacrificial layer of the fin-shaped laminated structure by using second mask patterns that are spaced apart from each other in the second direction and extend in the first direction.

20. The method of manufacturing a semiconductor memory device according to claim 18, further comprising:
forming a capacitor structure on the landing pad.
